(19) United States
(12) Patent Application Publication
(10) Pub. No.: US 2012/0168009 A1
(43) Pub. Date: Jul. 5, 2012

(54) FLEXIBLE DISPLAY APPARATUS AND FABRICATION METHOD OF FLEXIBLE DISPLAY APPARATUS

(75) Inventors: Kuang-Chung Chen, New Taipei City (TW); Ko-Pin Liao, Taipei City (TW); Chia-Hao Tsai, New Taipei City (TW); Jing-Yi Yan, Hsinchu County (TW)

(73) Assignee: INDUSTRIAL TECHNOLOGY RESEARCH INSTITUTE, Hsinchu (TW)

(21) Appl. No.: 13/105,899

(22) Filed: May 12, 2011

(30) Foreign Application Priority Data
Dec. 29, 2010 (TW) 99146618

(51) Int. Cl. F15D 1/00; B32B 38/00; B32B 38/10; H05K 1/00; B32B 37/02

(52) U.S. Cl. 137/560; 361/749; 361/750; 156/245; 156/247

(57) ABSTRACT

A flexible display apparatus including a first flexible film, a second flexible film, and a flexible display panel is provided. The second flexible film is disposed over the first flexible film, wherein a channel exists between the first flexible film and the second flexible film. The flexible display panel is disposed on the second flexible film. A fabrication method of a flexible display apparatus is also provided.

### CROSS-REFERENCE TO RELATED APPLICATION

This application claims the priority benefit of Taiwan application serial no. 99146618, filed Dec. 29, 2010. The entirety of the above-mentioned patent application is hereby incorporated by reference herein and made a part of this specification.

### TECHNICAL FIELD

The disclosure relates to a flexible display apparatus and a fabrication method thereof.

### BACKGROUND

With the progress of the display technology, a display becomes thinner and flatter, and the weight of the display is reduced as well, and the display occupies less space. As such, the display is easier to use and more beautiful for indoor application, and a user can no longer dispose a bulky cathode ray tube on a desk.

On the other hand, with a portable electronic device becomes smaller, the display also becomes smaller. However, when the electronic device becomes smaller, the display also becomes smaller. In this way, although the electronic device becomes portable, a too small display area causes much inconvenience for use, and the applicability is highly limited. For example, a too small display area can not display a high resolution frame. Moreover, a too small display area is hard to be watched by multiple users at the same time.

In recent years, a flexible display has been greatly developed. Since the flexible display can be rolled up so as to occupy less space, it is easy to carry. In addition, when the flexible display operates, it can be spread from a rolled-up state to a flat state, so that it can generate a display frame with a large area. As a result, the applicability of the display is increased.

Nevertheless, since plastic substrates or metal foils are used to replace glass substrates in a general flexible display, when the flexible display is spread out to use, the display is usually curved due to the residual stress inside the plastic substrates or the metal foils, but can not be flattened by itself. As such, when the user uses the flexible display, the hand of the user need press the edge of the flexible display to prevent the flexible from curving, which is very inconvenient for use.

### SUMMARY

One embodiment of the disclosure provides a fabrication method of a flexible display apparatus comprising following steps. A first flexible film is provided. A mold is provided, wherein the mold comprises a groove. A first flexible film is disposed over the mold and covers the groove. Gas between the first flexible film and the groove is extracted out so that a first portion of the first flexible film curves along a shape of the groove to adhere to the groove. A second flexible film is provided, wherein a Young's modulus of the second flexible film is greater than or equal to a Young's modulus of the first flexible film. The second flexible film and a second portion of the first flexible film are bonded so as to form a channel between the second flexible film and the first portion of the first flexible film. A flexible display panel is provided. The flexible display panel is bonded to one of the first flexible film and the second flexible film.

Another embodiment of the disclosure provides a fabrication method of a flexible display apparatus comprising following steps. A carrying substrate is provided. A debonding layer is formed on the carrying substrate. A first flexible film is formed on the carrying substrate and covers the debonding layer. A patterned debonding layer is formed on the first flexible film. A second flexible film is formed on the first flexible film, wherein the second flexible film covers the patterned debonding layer. A flexible display panel is formed on the second flexible film. The first flexible film is separated from the carrying substrate by debonding effect of the debonding layer.

Another embodiment of the disclosure provides a fabrication method of a flexible display apparatus comprising following steps. A carrying substrate is provided. A debonding layer is formed on the carrying substrate. A first flexible film is formed on the carrying substrate and covers the debonding layer. A patterned stress supporter is formed on the first flexible film. A second flexible film is formed on the first flexible film, wherein the second flexible film covers the patterned stress supporter. A flexible display panel is formed on the second flexible film. The first flexible film is separated from the carrying substrate by debonding effect of the debonding layer.

Another embodiment of the disclosure provides a flexible display apparatus comprising a first flexible film, a second flexible film, a patterned debonding layer, and a flexible display panel. The second flexible film is disposed over the first flexible film, wherein a channel exists between the first flexible film and the second flexible film. The patterned debonding layer is disposed inside the channel. The flexible display panel is disposed on the second flexible film.

Another embodiment of the disclosure provides a flexible display apparatus comprising a first flexible film, a second flexible film, a patterned stress supporter, and a flexible display panel. The second flexible film is disposed over the first flexible film. The patterned stress supporter is disposed between the first flexible film and the second flexible film. The flexible display panel is disposed on the second flexible film.

Several exemplary embodiments accompanied with figures are described in detail below to further describe the disclosure in details.

### BRIEF DESCRIPTION OF THE DRAWINGS

The accompanying drawings are comprised to provide further understanding, and are incorporated in and constitute a part of this specification. The drawings illustrate exemplary embodiments and, together with the description, serve to explain the principles of the disclosure.

FIG. 1A is a schematic perspective view of a flexible display apparatus in a contained state according to an exemplary embodiment.

FIG. 1B is a schematic perspective view of the flexible display apparatus of FIG. 1A in a spread-out state.

FIG. 2A is a schematic cross-sectional view of the flexible display apparatus in FIG. 1B along line I-I.

FIG. 2B is a top view of partial elements of the flexible display apparatus in FIG. 1B.

FIG. 3 is a schematic cross-sectional view of a flexible display apparatus according to another exemplary embodiment.

FIGS. 4A through 4D are schematic views showing the process of a fabrication method of a flexible display apparatus according to an exemplary embodiment.

FIGS. 5A through 5H are schematic views showing the process of a fabrication method of a flexible display apparatus according to another exemplary embodiment.

FIG. 6A is a schematic cross-sectional view of the flexible display apparatus made by the process of FIGS. 5A through 5H when being used.

FIG. 6B is a bottom view of the flexible display apparatus in FIG. 6A.

FIGS. 7A through 7D are schematic views showing the process of a fabrication method of a flexible display apparatus according to another exemplary embodiment.

FIG. 8 is a bottom view of the flexible display apparatus in FIG. 7D.

FIGS. 9A through 9C are schematic views showing the process of a fabrication method of a flexible display apparatus according to another exemplary embodiment.

FIGS. 10A through 10E are schematic views showing the process of a fabrication method of a flexible display apparatus according to another exemplary embodiment.

### DETAILED DESCRIPTION OF DISCLOSED EMBODIMENTS

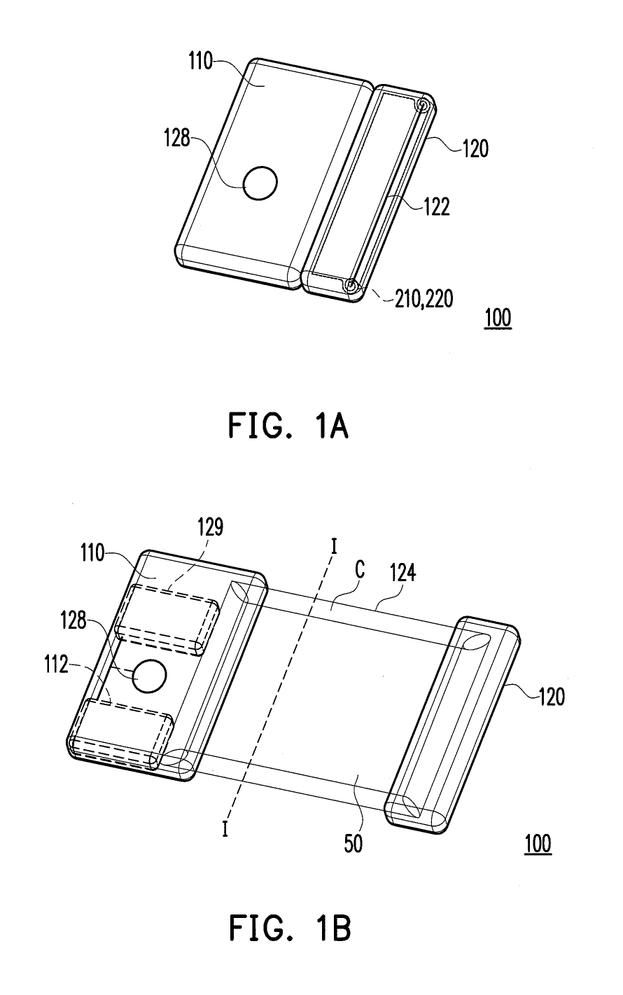

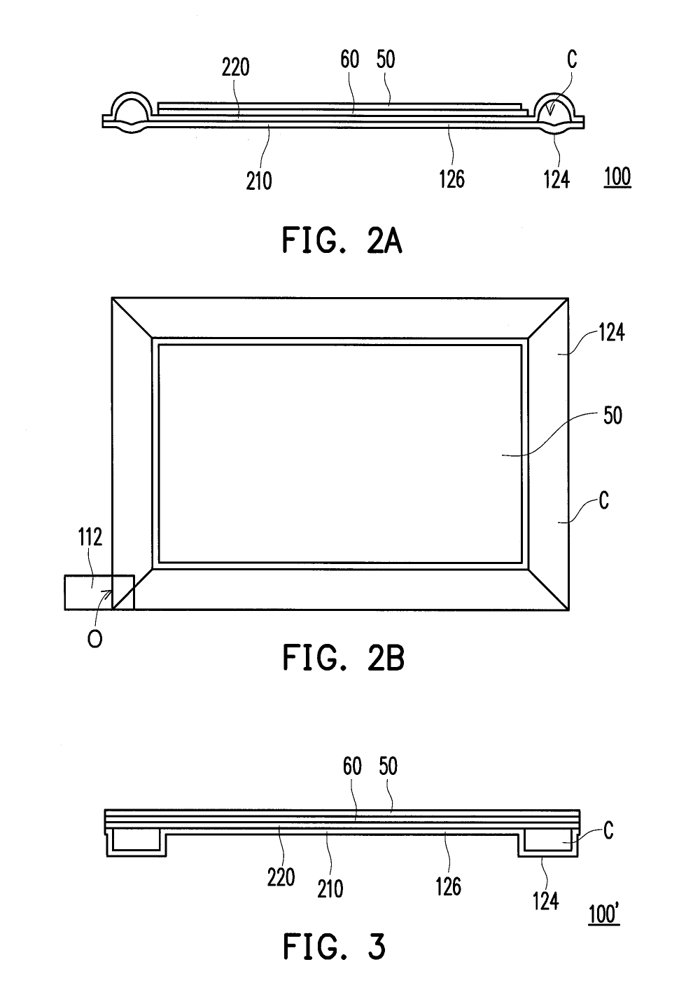

FIG. 1A is a schematic perspective view of a flexible display apparatus in a contained state according to an exemplary embodiment. FIG. 1B is a schematic perspective view of the flexible display apparatus of FIG. 1A in a spread-out state. FIG. 2A is a schematic cross-sectional view of the flexible display apparatus in FIG. 1B along line I-I. FIG. 2B is a top view of partial elements of the flexible display apparatus in FIG. 1B. Referring to FIGS. 1A, 1B, 2A, and 2B, the flexible display apparatus 100 in this embodiment comprises a first flexible film 210, a second flexible film 220, and a flexible display panel 50. The second flexible film 220 is disposed over the first flexible film 210, wherein a channel C exists between the first flexible film 210 and the second flexible film 220. The flexible display panel 50 is disposed on the second flexible film 220. In this embodiment, the flexible display panel 50 is, for example, an organic light emitting diode (OLED) panel, and the flexible display panel 50 adheres to the second flexible film 220 through an adhesive layer 60. However, in other embodiments, the flexible display panel may be a flexible liquid crystal display panel or an electronic paper.

In this embodiment, a channel C is formed between the second flexible film 220 and a first portion 124 of the first flexible film 210, and a second portion 126 of the first flexible film 210 is bonded to the second flexible film 220 for carrying the flexible display panel 50. In this embodiment, the channel C surrounds the second portion 126 and surrounds the flexible display panel 50. In addition, the first flexible film 210 and the second flexible film 220 are, for example, transparent plastic films, other transparent film made of flexible material, or other opaque film made of flexible material. For example, a material of the first flexible film 210 and the second flexible film 220 comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).

In this embodiment, the flexible display apparatus 100 further comprises a pump 112 communicating with the channel C, wherein the pump 112 is adapted to pump liquid or gas into the channel C (air being pumped into the channel C is taken as an example in FIG. 1B) for inflating the channel C, so as to flatten the flexible display panel 50. By the inflation of the channel C, the first flexible film 210 and the second flexible film 220 are flattened but not curved, so that the flexible display panel 50 adhering to the second flexible film 220 is flattened but not curved. In this way, the flexible display apparatus 100 can flattened by itself, and need not be pressed by the hand of a user. As a result, the flexible display apparatus 100 has the characteristic of being easy to use. In addition, when the flexible display apparatus 100 is carried, gas or liquid in the channel C is extracted out. For example, air in the channel C is extracted out by the pump 112. Alternatively, the channel C is pressed so that the gas in the channel C is extracted out from the opening O of the channel C. In this way, the first flexible film 210, the second flexible film 220, and the flexible display panel 50 may be rolled up so as to occupy less space and be easy to contain and carry.

In this embodiment, the flexible display apparatus 100 further comprises a containing box 120, a power supply module 129, and a control box 110. The first flexible film 210, the second flexible film 220, and the flexible display panel 50 is adapted to be contained in the containing box 120 when the channel C is not inflated. For example, a reel 122 may be disposed in the containing box 120, and the first flexible film 210, the second flexible film 220, and the flexible display panel 50 may be rolled up on the reel 122 to be contained in the containing box 120. The power supply module 129 is electrically connected to the pump 112 for driving the pump 112. The control box 110 contains the pump 112 and the power supply module 129. In this embodiment, the flexible display apparatus 100 further comprises a user operation interface 128 disposed on the control box 110 and electrically connected to the pump 112. The user operation interface 128 is, for example, a button. When the user presses the button, the power supply module 129 drives the pump 112, so that the pump 112 pumps air into the channel C.

When the first flexible film 210, the second flexible film 220, and the flexible display panel 50 is contained in the containing box 120, the containing box 120 and the control box 110 may be bonded together, so as to reduce the volume thereof and be easy to carry. In an embodiment, the containing box 120 and the control box 110 may be bonded together through a bolt or another bonding element. In addition, when the flexible display apparatus 100 is used, the containing box 120 and the control box 110 may be pulled apart so that a part of the first flexible film 210, a part of the second flexible film 220, and the flexible display panel 50 are exposed outside the containing box 120. Then, by inflating the channel C, the flexible display apparatus 100 may flattened by itself. In other embodiments, the pump 112 is not used to inflate, but the user blow air into the channel C from the opening O of the channel C so as to inflate the channel C.

FIG. 3 is a schematic cross-sectional view of a flexible display apparatus according to another exemplary embodiment. Referring to FIG. 3, the flexible display apparatus 100′ in this embodiment is similar to the flexible display apparatus 100 in FIG. 2A, and the difference therebetween is as follows. In the flexible display apparatus 100 in FIG. 2A, the channel C surrounds the flexible display panel 50. However, in the flexible display apparatus 100′ in this embodiment, the channel C is disposed under the flexible display panel 50, but the channel C still surrounds the second portion 126 of the first flexible film 210.

In the above embodiments, the channel C is in a frame shape, but the disclosure is not limited thereto. In other embodiments, the channel C may be in other shapes, for example, in a lattice shape or another shape which is able to flatten the flexible display panel 50.

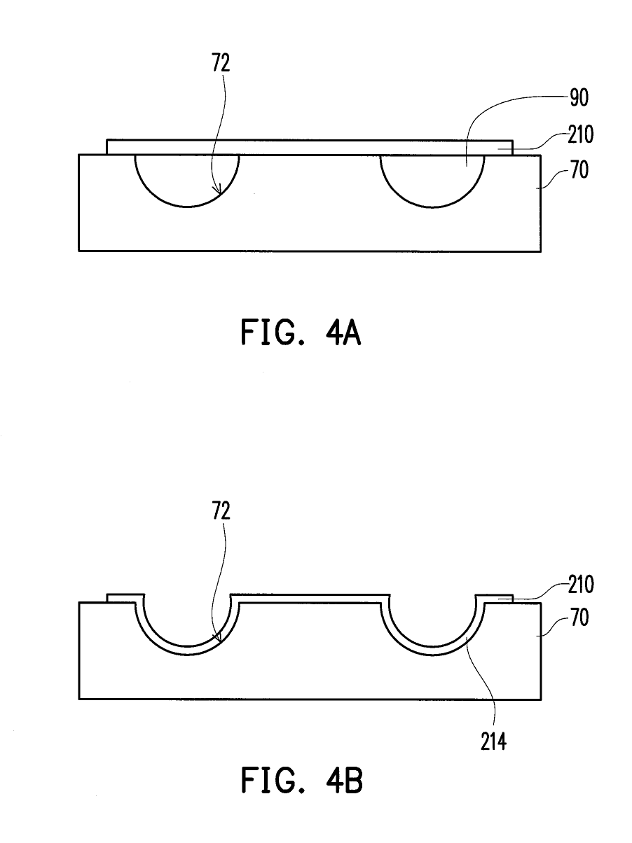

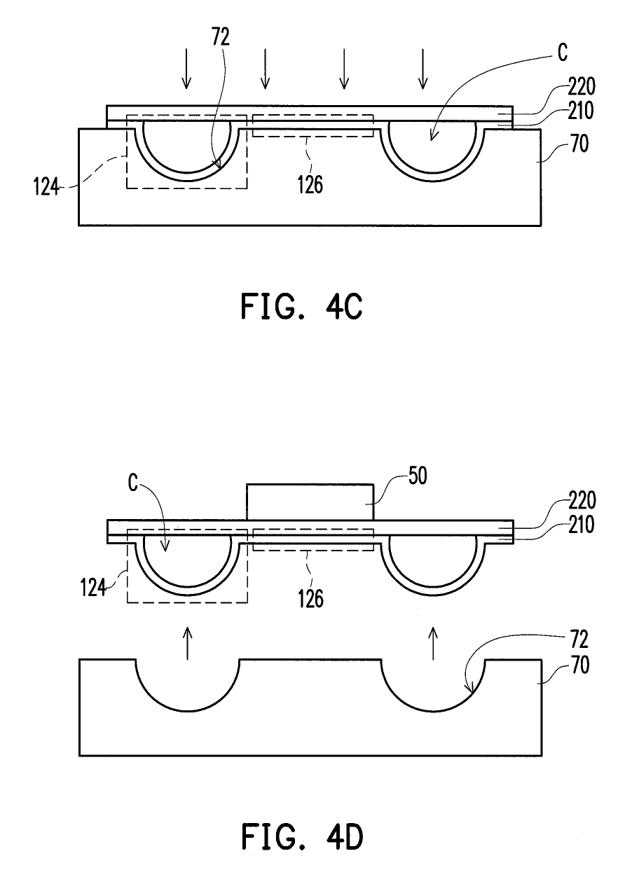

FIGS. 4A through 4D are schematic views showing the process of a fabrication method of a flexible display apparatus according to an exemplary embodiment. The fabrication method of the flexible display apparatus in this embodiment may be used to fabricate the flexible display apparatus in FIG. 1A. The fabrication method of the flexible display apparatus in this embodiment comprises following steps. First, referring to FIG. 4A, a first flexible film 210 is provided. Next, a mold 70 is provided, wherein the mold 70 comprises a groove 72. Then, a first flexible film 210 is disposed over the mold 70 and covers the groove 72. Afterwards, referring to FIG. 4B, gas 90 between the first flexible film 210 and the groove 72 is extracted out so that a first portion 214 of the first flexible film 210 curves along the shape of the groove 72 to adhere to the groove 72. For example, the groove 72 may have a plurality of gas inlet holes, and an extracting pump may be used to extract out the gas 90 through the gas inlet holes. After that, referring to FIG. 4C, a second flexible film 220 is provided, wherein the Young's modulus of the second flexible film 220 is greater than or equal to the Young's modulus of the first flexible film 210. That is, the first flexible film 210 is softer than the second flexible film 220, or is as soft as the second flexible film 220. Then, the second flexible film 220 and a second portion 126 of the first flexible film 210 are bonded so as to form a channel C between the second flexible film 220 and the first portion 124 of the first flexible film 210. In this embodiment, the opening O as shown in FIG. 2B may be reserved at a certain position of the channel C at this time. Next, referring to FIG. 4D, a flexible display panel 50 is provided. Then, the flexible display panel 50 is bonded to one of the first flexible film 210 and the second flexible film 220, and the flexible display panel 50 being bonded to the second flexible film 220 is taken as an example in FIG. 4D.

In this embodiment, the flexible display panel 50 is disposed on the second portion 126 of the first flexible film 210, and the channel C is at the periphery of the channel C. In this way, the flexible display apparatus 100 as shown in FIG. 2A is formed. However, in another embodiment, the flexible display panel 50 is disposed on both the first portion 214 and the second portion 216 of the first flexible film 210, so as to form the flexible display apparatus 100′ as shown in FIG. 3. By the above fabrication method, the flexible display apparatuses 100 and 100′ capable of being flattened by itself is formed.

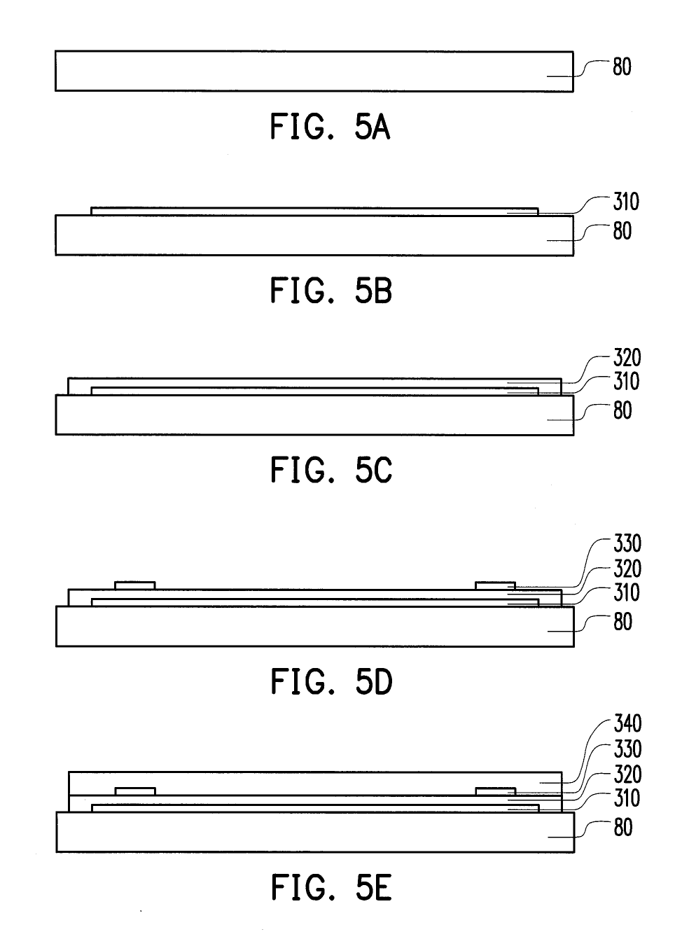

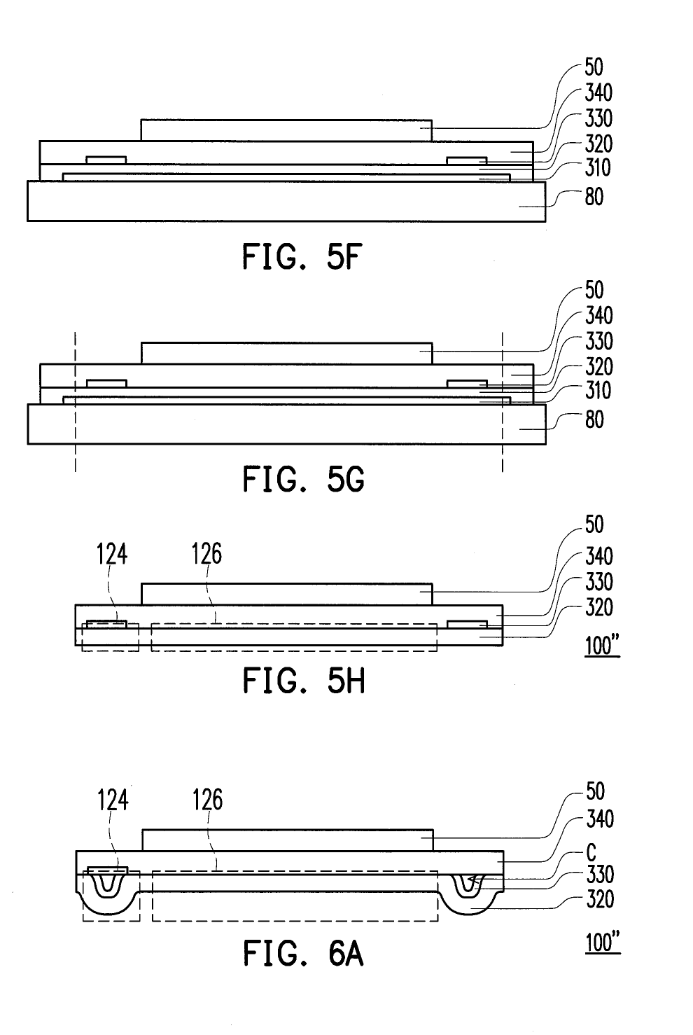

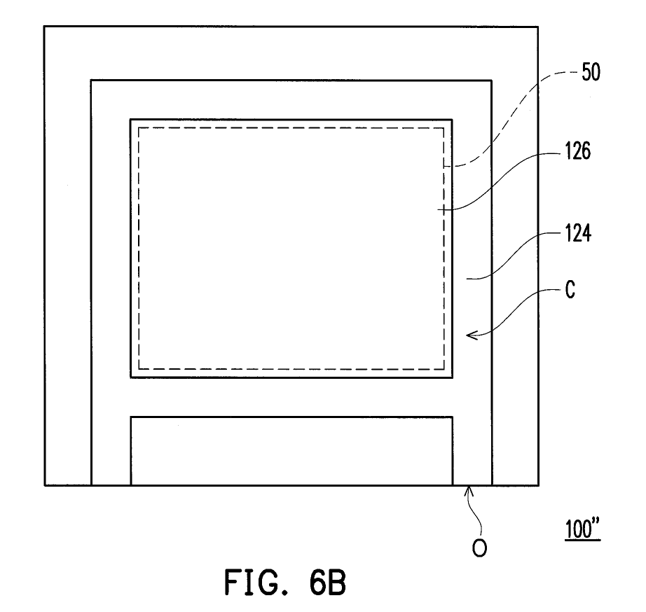

FIGS. 5A through 5H are schematic views showing the process of a fabrication method of a flexible display apparatus according to another exemplary embodiment. FIG. 6A is a schematic cross-sectional view of the flexible display apparatus made by the process of FIGS. 5A through 5H when being used. FIG. 6B is a bottom view of the flexible display apparatus in FIG. 6A. The fabrication method of the flexible display apparatus in this embodiment may be used to fabricate a flexible display apparatus similar to that shown in FIGS. 1A and 1B. The fabrication method of the flexible display apparatus in this embodiment comprises following steps. First, referring to FIG. 5A, a carrying substrate 80 is provided, which is, for example, a glass substrate or another rigid substrate. Next, referring to FIG. 5B, a debonding layer 310 is formed on the carrying substrate 80. After that, a first flexible film 320 is formed on the carrying substrate 80 and covers the debonding layer 310. Afterwards, referring to FIG. 5D, a patterned debonding layer 330 is formed on the first flexible film 320. In this embodiment, the patterned debonding layer 330 extends in a ring shape as that of the channel C shown in FIG. 1B, but the disclosure is not limited thereto. Then, referring to FIG. 5E, a second flexible film 340 is formed on the first flexible film 320, and the second flexible film 340 covers the patterned debonding layer 330. In this embodiment, the material of the first flexible film 320 and the second flexible film 340 is, for example, transparent plastics, other transparent flexible materials, other opaque plastics, or other opaque flexible materials. For example, a material of the first flexible film 320 and the second flexible film 340 comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK). After that, referring to FIG. 5F, a flexible display panel 50 is formed on the second flexible film 340. Afterwards, the first flexible film 330 is separated from the carrying substrate 80 by the debonding effect of the debonding layer 310. In this embodiment, referring to FIG. 5G, the first flexible film 330 being separated from the carrying substrate 80 by the debonding effect of the debonding layer 310 comprises following steps. First, cutting off the edges of the first flexible film 320 and the second flexible film 340 and cutting to the debonding layer 310 are performed. In this way, all the rest first flexible film 320 not cut off is connected to the carrying substrate 80 through the debonding layer 310, but does not directly connect the carrying substrate 80. Since the debonding layer 310 has the characteristic of being easy to strip off from the first flexible film 320 and the carrying substrate 80 or reducing the bonding force between the first flexible film 320 and the carrying substrate 80, the rest flexible film 320 and the carrying substrate 80 are separated by the debonding effect of the debonding layer 310. That is to say, the first flexible film 320, the second flexible film 340, and the flexible display panel 50 together are separated from the carrying substrate 30, as shown in FIG. 5H. In this way, the main structure of the flexible display apparatus 100″ is formed. The material of the debonding layer 310 and the patterned debonding layer 330 is, for example, a polymer containing poly-para-xylylene (i.e. parylene) or a compound containing silicon. The polymer containing poly-para-xylylene is, for example, parylene-N, parylene-C, parylene-D, or parylene-F, and the compound containing silicon is, for example, the compound containing silicon nitride (SiNₓ), silicon oxide (SiO_{y}), or silane, wherein x and y are both greater than 0. However, in other embodiments, the material of the debonding layer 310 and the patterned debonding layer 330 may be another material having debonding effect, and the disclosure does not limit the material of the debonding layer 310 and the patterned debonding layer 330 to the above two series of compounds.

Next, referring to FIGS. 5H, 6A, and 6B, the flexible display apparatus 100″ in this embodiment is similar to the flexible display apparatus 100 in FIGS. 1B and 2A, and the difference therebetween is as follows. When the flexible display apparatus 100″ in this embodiment is in operation, gas, e.g. air, or liquid may be poured into the position of the patterned debonding layer 330 between the first flexible film 320 and the second flexible film 340, e.g. gas being poured into through the opening O as shown in FIG. 6B. Since the patterned debonding layer 330 has the characteristic of being easy to strip off from the first flexible film 320 and the second flexible film 340 or reducing the bonding force between the first flexible film 320 and the second flexible film 340, when the gas or liquid is poured into, a channel C is formed at the position of the patterned debonding layer 330 between the first flexible film 320 and the second flexible film 340. Along with the channel C is filled with gas or liquid and inflated, the flexible display apparatus 100″ may be flattened by itself. The difference between the flexible display apparatus 100″ in this embodiment and the flexible display apparatus 100 in FIG. 1A lies in that, in the flexible display apparatus 100″, the patterned debonding layer 330 exists in the channel C. In addition, the reel 122, the containing box 120, the control box 110, the pump 112, the power supply module 129, and the user operation module 128 may be disposed in the flexible display apparatus 100″ as those shown in FIGS. 1A and 1B, and the details thereof are referred to the embodiment of FIGS. 1A and 1B but not repeated herein.

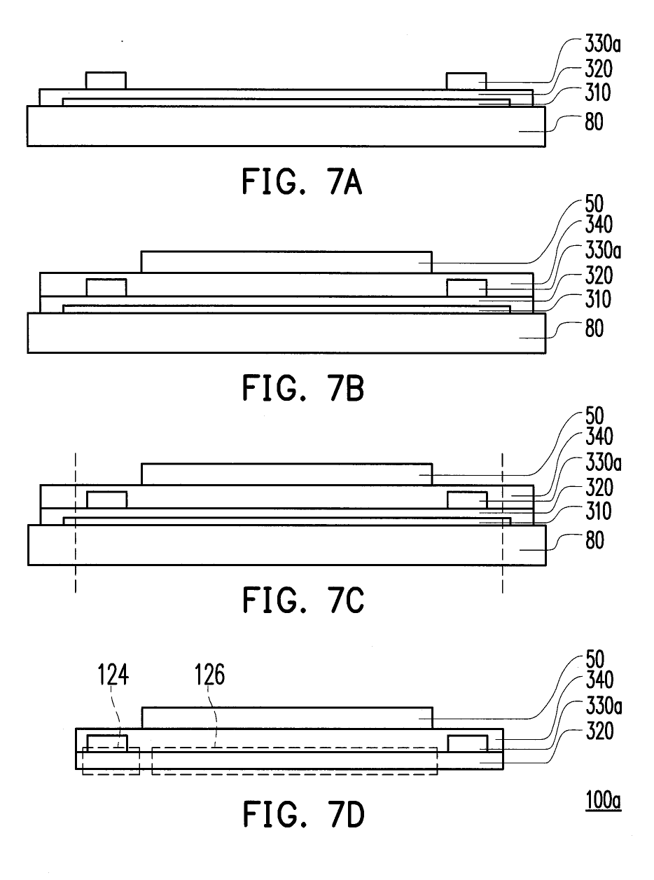

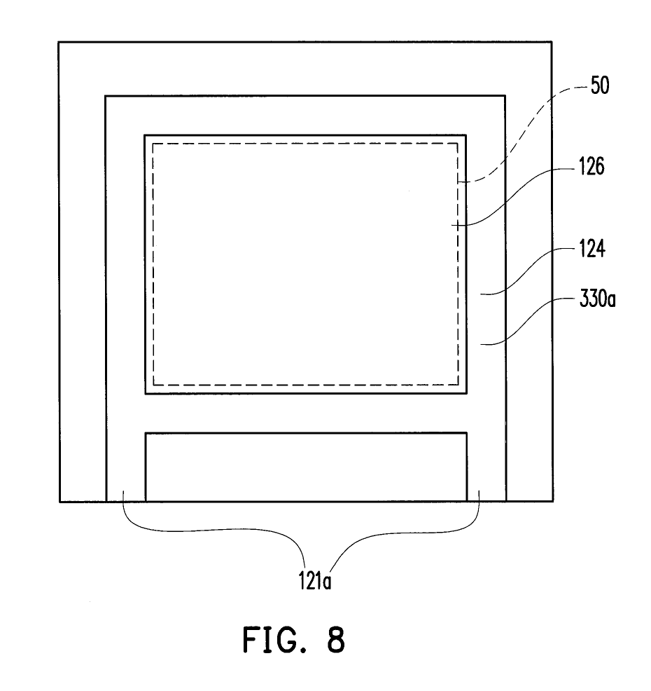

FIGS. 7A through 7D are schematic views showing the process of a fabrication method of a flexible display apparatus according to another exemplary embodiment. FIG. 8 is a bottom view of the flexible display apparatus in FIG. 7D. The fabrication method of the flexible display apparatus in this embodiment is similar to the fabrication method of the flexible display apparatus shown in FIGS. 5A through 5H, and the difference therebetween is as follows. Referring to FIG. 7A, in the fabrication method of this embodiment, the patterned debonding layer 330 in FIG. 5C is replaced by the patterned stress supporter 330a. The step in FIG. 7A is similar to that in FIG. 5C, and the difference therebetween is as follows. In the step of FIG. 7A in this embodiment, the patterned stress supporter 330a is formed on the first flexible film 320. The step in FIG. 7B is similar to that in FIG. 5D, and the difference therebetween is as follows. In this embodiment, when the second flexible film 340 is formed on the first flexible film 320, the second flexible film 340 covers the patterned stress supporter 330a. The other detail steps in this embodiment are referred to the embodiment of FIGS. 5A through 5H, and not repeated herein. For example, the steps of FIGS. 7C and 7D is the same as the steps of FIGS. 5G and 5H. After the step of FIG. 7D is finished, the main structure of the flexible display apparatus 100a is formed. In this embodiment, the material of the patterned stress supporter 330a is a shape memory effect (SME) material. For example, the SME material is, for example, an SME alloy or an SME plastic. However, in other embodiments, the material of the patterned stress supporter 330a may be a hyperelastic alloy.

Referring to FIGS. 7D and 8, the flexible display apparatus 100a in this embodiment is similar to the flexible display apparatus 100 in FIGS. 1A, 1B, and 2A, and the difference therebetween lies in that the channel C in FIG. 1B is replaced by the patterned stress supporter 330a in the flexible display apparatus 100a in FIG. 7D. In addition, in this embodiment, the power supply module 129 and the pump 112 in FIG. 1B may be replaced by a current supply module in this embodiment. The current supply module is electrically connected to the patterned stress supporter 330a, e.g. the current supply module being connected to the end 121a of the patterned stress supporter 330a exposed at one side of the first flexible film 320 and the second flexible film 340 through a conductive wire so as to electrically connect to the patterned stress supporter 330a. The current supply module is adapted to supply a current to the patterned stress supporter 330a for increasing a temperature of the SME material to over a transition temperature of the SME material, so as to recover the shape of the patterned stress supporter 330a to a state for flattening the flexible display panel. Specifically, when the temperature of the SME material is higher than the transition temperature, e.g. being higher than the room temperature, the shape of the patterned stress supporter 330a recovers to a memorized shape similar to the shape of the channel C shown in FIG. 1B, e.g. a frame shape or a ring shape. When the temperature of the patterned stress supporter 330a is lower than the transition temperature of the SME material, e.g. being at the room temperature, the patterned stress supporter 330a may curved freely, and the first flexible film 320, the second flexible film 340, and the flexible display panel 50 are adapted to be contained in the containing box 120. On the other hand, when the flexible display apparatus 100a is used, the user may command the current supply module electrically connected to the user operation interface 128 to apply a current to the patterned stress supporter 330a through the user operation interface 128, so as to increase the temperature of the patterned stress supporter 330a to over the transition temperature. In this way, the shape of the patterned stress supporter 330a may recover to the memorized shape, e.g. the frame shape or the ring shape of the channel C shown in FIG. 1B, so that the flexible display apparatus 100a is flattened by itself.

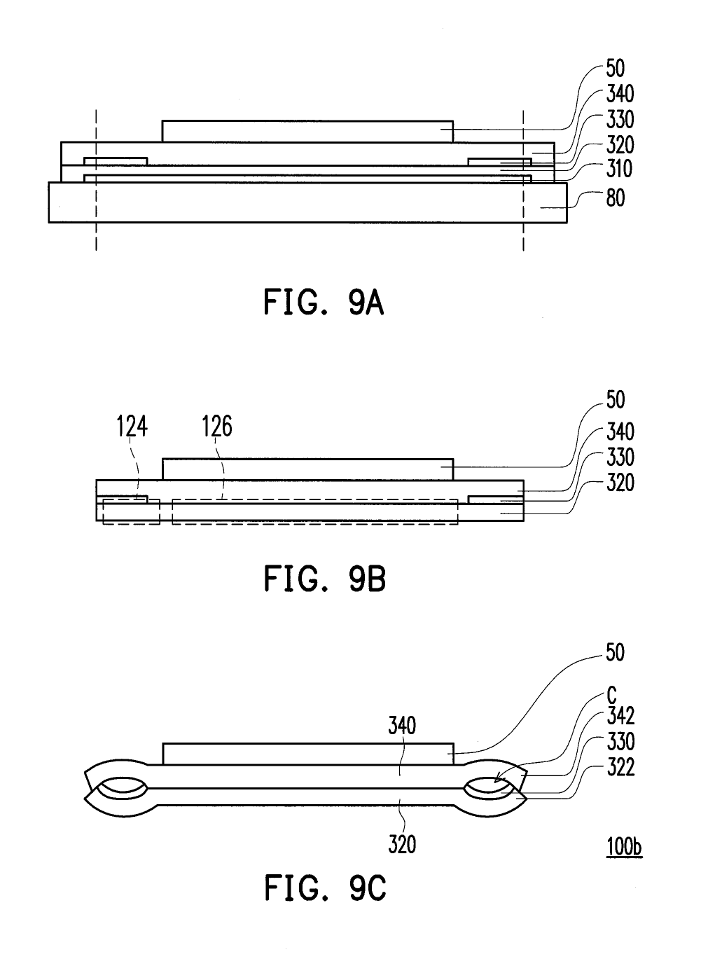

FIGS. 9A through 9C are schematic views showing the process of a fabrication method of a flexible display apparatus according to another exemplary embodiment. The fabrication method of the flexible display apparatus in this embodiment is similar to the fabrication method of the flexible display apparatus shown in FIGS. 5A through 5H, and the difference therebetween is as follows. In the fabrication method of the flexible display apparatus in this embodiment, the step of FIG. 9A is similar to the step of FIG. 5G, and the difference therebetween is as follows. In this embodiment, when cutting off the edges of the first flexible film 320 and the second flexible film 340 is performed, cutting to the patterned debonding layer 330 is performed in addition to cutting to the debonding layer 310. Next, the step of FIG. 9B is similar to the step of FIG. 5H, and the difference therebetween is as follows. In the step of FIG. 9B, an edge of the first flexible film 320 is separated from an edge of the second flexible film 340 by debonding effect of the patterned debonding layer 330 and a channel C between the edge of the first flexible film 320 and the edge of the second flexible film 340 is formed. Then, referring to FIG. 9C, the edge 322 of the first flexible film 320 is connected with the edge 342 of the second flexible film 340 and the channel C is retained. For example, hot melt adhering is used to connect the edge 322 of the first flexible film 320 with the edge 342 of the second flexible film 340. In this way, the main structure of the flexible display apparatus 100b is formed.

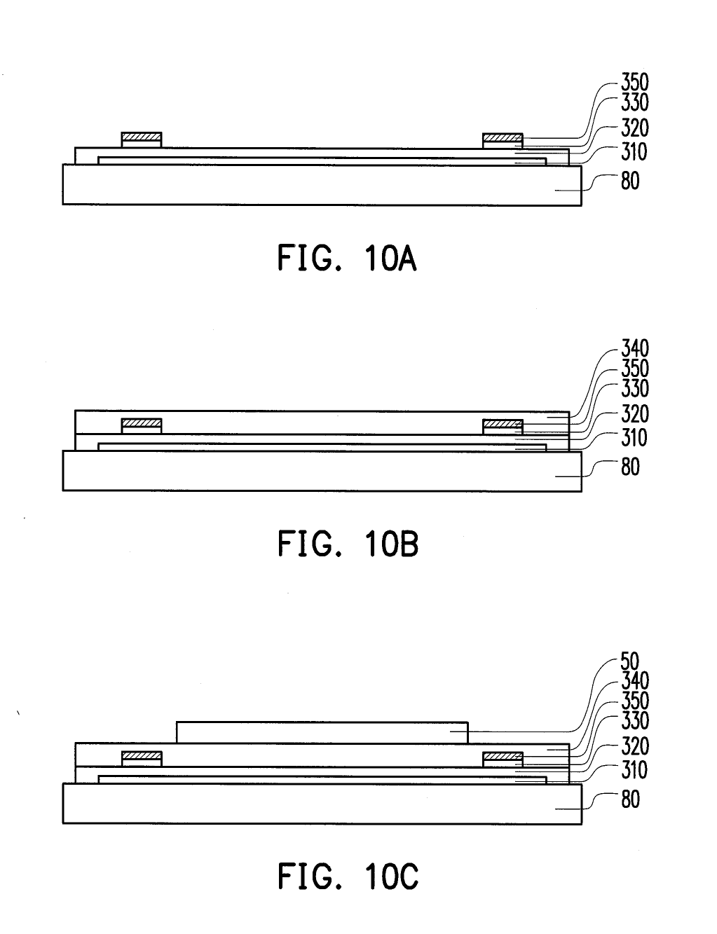

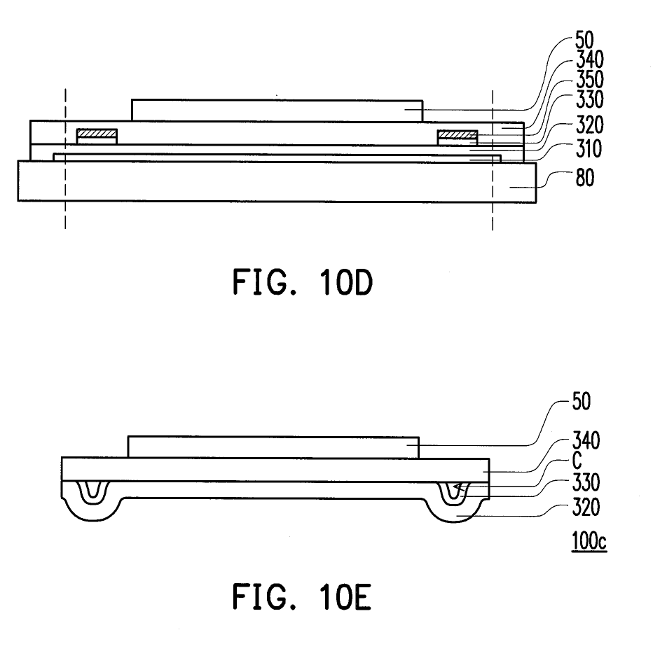

FIGS. 10A through 10E are schematic views showing the process of a fabrication method of a flexible display apparatus according to another exemplary embodiment. The fabrication method of the flexible display apparatus in this embodiment is similar to the fabrication method of the flexible display apparatus shown in FIGS. 5A through 5H, and the difference therebetween is as follows. The step in FIG. 10A is similar to that in FIG. 5C, and the difference therebetween is as follows. In this embodiment, after the patterned debonding layer 330 is formed on the first flexible film 320, a patterned sacrificial layer 350 is formed on the patterned debonding layer. In this embodiment, the shape of the patterned debonding layer 330 is similar to the shape of the patterned sacrificial layer 350. Next, the step in FIG. 10B is similar to that in FIG. 5D, and the difference therebetween is as follows. In this embodiment, when the second flexible film 340 is formed on the first flexible film 320, the second flexible film 340 covers the patterned debonding layer 330 and the patterned sacrificial layer 350. The step of FIG. 10D is the same as the step of FIG. 5G, and the details thereof are repeated herein. The other detail steps in this embodiment are referred to the embodiment of FIGS. 5A through 5H, and not repeated herein. In addition, in the embodiment, the step of FIG. 10E is also performed. In the step of FIG. 10E, the patterned sacrificial layer 350 is gasified to form a channel C, wherein the channel C is located between the first flexible film 320 and the second flexible film 340. In this way, the main structure of the flexible display apparatus 100c is formed. The material of the patterned sacrificial layer 350 is, for example, the material capable of being gasified with the change of the external condition. For example, in this embodiment, the material of the patterned sacrificial layer 350 is, for example, the material capable of being gasified when receiving heat, and the step of gasifying the patterned sacrificial layer 350, is for example, heating the whole structure or heating the patterned sacrificial layer 350, so that the patterned sacrificial layer 350 is gasified due to receiving heat.

In the above embodiments, when the first flexible film 310, 310, the second flexible film 220, 320, and the channel C (or the patterned stress supporter 330a) is finished, it can be selected to remove the second portion 126 of the first flexible film 210, 310, so that the rest first portion 124 of the first flexible film 210, 310 and the second flexible film 220, 320 wrap the channel C or wrap the patterned stress supporter 330a.

Moreover, in the flexible display apparatus having the channel C in the above embodiments, e.g. the flexible display apparatuses 100, 100′, 100″, 100b, and 100c, gas having density less than that of air may be poured into the channel C, or gas or liquid having density less than that of water may be poured into the channel C. Specifically, the flexible display apparatuses in the above embodiments may be applied as a float information display board, and a wire having an end fixed on an object may extend to and connect with the flexible display apparatus. When gas having density less than that of air is poured into the channel C, the flexible display apparatus may float in the air to serve as a float display having supporting and floating effects and even to apply to an outdoor float advertisement. When gas or liquid having density less than that of water is poured into the channel C, the flexible display apparatus may float in the water or on the water to serve as a float display having supporting and floating effects. For example, the flexible display apparatus floats in an aquarium to serve as a fish information board or an advertisement or an information board on the water.

In view of the above, in the flexible display apparatus and the fabrication method of the flexible display apparatus according to the embodiments of the disclosure, since the channel or the patterned stress supporter is formed between the first flexible film and the second flexible film, the flexible display apparatus is flattened by itself due to the inflation of the channel or the stress of the patterned stress supporter and can be not curved. As such, the flexible display apparatus is easy to use, and the user need not press the flexible display apparatus by hands to prevent the flexible display apparatus from curving.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A fabrication method of a flexible display apparatus, comprising:
providing a first flexible film;
providing a mold, wherein the mold comprises a groove;
disposing the first flexible film over the mold, wherein the first flexible film covers the groove;
extracting out gas between the first flexible film and the groove so that a first portion of the first flexible film curves along a shape of the groove to adhere to the groove;
providing a second flexible film, wherein a Young's modulus of the second flexible film is greater than or equal to a Young's modulus of the first flexible film;
bonding the second flexible film and a second portion of the first flexible film so as to form a channel between the second flexible film and the first portion of the first flexible film;
providing a flexible display panel; and
bonding the flexible display panel to one of the first flexible film and the second flexible film.

2. The fabrication method of the flexible display apparatus according to claim 1, wherein the flexible display panel is disposed over the second portion of the first flexible film, and the channel is located at a periphery of the flexible display panel.

3. The fabrication method of the flexible display apparatus according to claim 1, wherein the flexible display panel is disposed over the first portion and the second portion of the first flexible film.

4. The fabrication method of the flexible display apparatus according to claim 1, wherein a material of the first flexible film and the second flexible film comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).

5. A fabrication method of a flexible display apparatus, comprising:
providing a carrying substrate;
forming a debonding layer on the carrying substrate;
forming a first flexible film on the carrying substrate, wherein the first flexible film covers the debonding layer;
forming a patterned debonding layer on the first flexible film;
forming a second flexible film on the first flexible film, wherein the second flexible film covers the patterned debonding layer;
forming a flexible display panel on the second flexible film; and
separating the first flexible film from the carrying substrate by debonding effect of the debonding layer.

6. The fabrication method of the flexible display apparatus according to claim 5, wherein separating the first flexible film from the carrying substrate by the debonding effect of the debonding layer comprises:
cutting off edges of the first flexible film and the second flexible film and cutting to the debonding layer; and
separating a rest portion of the first flexible film from the carrying substrate by the debonding effect of the debonding layer.

7. The fabrication method of the flexible display apparatus according to claim 5, wherein separating the first flexible film from the carrying substrate by the debonding effect of the debonding layer comprises:
cutting off edges of the first flexible film and the second flexible film and cutting to the debonding layer and the patterned debonding layer; and
separating a rest portion of the first flexible film from the carrying substrate by the debonding effect of the debonding layer, and
the fabrication method of the flexible display apparatus further comprises:
separating an edge of the first flexible film from an edge of the second flexible film by debonding effect of the patterned debonding layer and forming a channel between the edge of the first flexible film and the edge of the second flexible film; and
connecting the edge of the first flexible film with the edge of the second flexible film and retaining the channel.

8. The fabrication method of the flexible display apparatus according to claim 5, further comprising:
forming a patterned sacrificial layer on the patterned debonding layer after forming the patterned debonding layer on the first flexible film, wherein when the second flexible film is formed on the first flexible film and when the second flexible film covers the patterned debonding layer, the second flexible film covers the patterned sacrificial layer.

9. The fabrication method of the flexible display apparatus according to claim 8, further comprising:
gasifying the patterned sacrificial layer to form a channel, wherein the channel is located between the first flexible film and the second flexible film.

10. The fabrication method of the flexible display apparatus according to claim 5, wherein a material of the first flexible film and the second flexible film comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).

11. The fabrication method of the flexible display apparatus according to claim 5, wherein a material of the debonding layer and the patterned debonding layer comprises a polymer containing poly-para-xylylene or a compound containing silicon.

12. A fabrication method of a flexible display apparatus, comprising:
providing a carrying substrate;
forming a debonding layer on the carrying substrate;
forming a first flexible film on the carrying substrate, wherein the first flexible film covers the debonding layer;
forming a patterned stress supporter on the first flexible film;
forming a second flexible film on the first flexible film, wherein the second flexible film covers the patterned stress supporter;
forming a flexible display panel on the second flexible film; and
separating the first flexible film from the carrying substrate by debonding effect of the debonding layer.

13. The fabrication method of the flexible display apparatus according to claim 12, wherein separating the first flexible film from the carrying substrate by the debonding effect of the debonding layer comprises:
cutting off edges of the first flexible film and the second flexible film and cutting to the debonding layer; and
separating a rest portion of the first flexible film from the carrying substrate by the debonding effect of the debonding layer.

14. The fabrication method of the flexible display apparatus according to claim 12, wherein a material of the patterned stress supporter is a shape memory effect (SME) material.

15. The fabrication method of the flexible display apparatus according to claim 14, wherein the SME material is an SME alloy or an SME plastic.

16. The fabrication method of the flexible display apparatus according to claim 12, wherein a material of the patterned stress supporter is a hyperelastic alloy.

17. The fabrication method of the flexible display apparatus according to claim 12, wherein a material of the first flexible film and the second flexible film comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).

18. The fabrication method of the flexible display apparatus according to claim 12, wherein a material of the debonding layer comprises a polymer containing poly-para-xylylene or a compound containing silicon.

19. A flexible display apparatus, comprising:
a first flexible film;
a second flexible film disposed over the first flexible film, wherein a channel exists between the first flexible film and the second flexible film;
a patterned debonding layer disposed inside the channel; and
a flexible display panel disposed on the second flexible film.

20. The flexible display apparatus according to claim 19 further comprising a pump communicating with the channel, wherein the pump is adapted to pump liquid or gas into the channel for inflating the channel, so as to flatten the flexible display panel.

21. The flexible display apparatus according to claim 20 further comprising:
a containing box, wherein the first flexible film, the second flexible film, and the flexible display panel is adapted to be contained in the containing box when the channel is not inflated;
a power supply module electrically connected to the pump for driving the pump; and
a control box containing the pump and the power supply module.

22. The flexible display apparatus according to claim 21 further comprising a user operation interface disposed on the control box and electrically connected to the pump.

23. The flexible display apparatus according to claim 19, wherein a material of the first flexible film and the second flexible film comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).

24. The flexible display apparatus according to claim 19, wherein a material of the patterned debonding layer comprises a polymer containing poly-para-xylylene or a compound containing silicon.

25. A flexible display apparatus, comprising:
a first flexible film;
a second flexible film disposed over the first flexible film;
a patterned stress supporter disposed between the first flexible film and the second flexible film; and
a flexible display panel disposed on the second flexible film.

26. The flexible display apparatus according to claim 25, wherein a material of the patterned stress supporter is a shape memory effect (SME) material.

27. The flexible display apparatus according to claim 26, wherein the SME material is an SME alloy or an SME plastic.

28. The flexible display apparatus according to claim 26 further comprising a current supply module electrically connected to the patterned stress supporter, wherein the current supply module is adapted to apply a current to the patterned stress supporter for increasing a temperature of the SME material to over a transition temperature of the SME material, so as to recover a shape of the patterned stress supporter to a state for flattening the flexible display panel.

29. The flexible display apparatus according to claim 28 further comprising:
a containing box, wherein the first flexible film, the second flexible film, the patterned stress supporter, and the flexible display panel are adapted to be contained in the containing box when a temperature of the patterned stress supporter is lower than the transition temperature of the SME material; and
a control box containing the current supply module.

30. The flexible display apparatus according to claim 29 further comprising a user operation interface disposed on the control box and electrically connected to the current supply module.

31. The flexible display apparatus according to claim 25, wherein a material of the first flexible film and the second flexible film comprises polypropylene (PP), polyamide, polyimide (PI), polyurethane (PU), polycarbonate (PC), polyethylene (PE), polyacrylate (PA), polyethersulfone (PES), polyethylene terephthalate (PET), polyethylene naphthalate (PEN), polyetherimide (PEI), polynorbornene (PNB), or polyetheretherketone (PEEK).
